(19) United States
(12) Patent Application Publication
(10) Pub. No.: US 2011/0097899 A1
(43) Pub. Date: Apr. 28, 2011

(54) METHOD OF FORMING FUNNEL-SHAPED OPENING

(75) Inventor: Lee-Chuan Tseng, Taipei City (TW)

(73) Assignee: NANYA TECHNOLOGY CORPORATION, Taoyuan (TW)

(21) Appl. No.: 12/604,373

(22) Filed: Oct. 22, 2009

(51) Int. Cl. H01L 21/311

(52) U.S. Cl. 438/694; 257/E21.249

(57) ABSTRACT

A method of forming a funnel-shaped opening is provided. First, a substrate is provided, wherein a conductive layer is formed on the substrate. Then, a dielectric layer is formed over the conductive layer. Further, a first opening is formed in the dielectric layer, wherein the first opening exposes the conductive layer. Thereafter, a portion of the dielectric layer at a top corner of the first opening is removed to form a second opening by an etching gas containing argon in a reaction chamber, wherein a power of the reaction chamber is about 500˜1800 W.

### BACKGROUND OF THE INVENTION

1. Field of the Invention

This present invention relates to a semiconductor process. More particularly, the present invention relates to a method for forming a funnel-shaped opening.

2. Description of Related Art

With advancement of semiconductor technologies, dimensions of the semiconductor devices have continuously miniaturized. As the integration degree of integrated circuits (IC) is up to a certain level, a die surface is insufficient for forming all interconnects thereon. Hence, multi-level interconnects are adopted in current very-large scale integrated (VLSI) circuits.

As regards to the current process of manufacturing a metallic interconnect, a damascene technique is often employed to form the metallic interconnect. In a damascene process, generally, the openings are formed in a dielectric layer, and then the openings are filled with metal to form an interconnect. However, when the aperture ratio of the opening is relatively large, the step coverage of the metal material is relatively poor. Therefore, the interconnect is formed with defects, such as voids, which seriously affect the electrical performance of the semiconductor device.

Hence, in order to improve the gap-filling capability of the metal material, especially the metal material layer filling the openings by sputtering, the funnel-shaped openings are formed in the dielectric layer. The funnel-shaped opening includes a lower portion with a perpendicular sidewall and an upper portion in a cone shape or a bowl shape communicated with the lower portion. Typically, the funnel-shaped opening can be formed by the wet-by-dry etching process. That is the opening is formed by simultaneously performing the dry etching process and the wet etching process. Further, the anisotropic etching characteristic of the dry etching process is used to form the opening with the sidewall substantially perpendicular to the bottom of the opening and the isotropic etching characteristic of the wet etching process is used to change the dimension of the opening. Therefore, in the method for forming the funnel-shaped opening, with the increase of the etched depth of the dielectric layer etched by the wet-by-dry etching process, the etching degree is decreased by decreasing the time for performing the wet etching process so that the opening is formed with the lower portion having a uniform dimension and the upper portion with an increasingly enlarged dimension from the bottom to the top. Alternatively, in another method for forming the funnel-shaped opening, a multi-layered dielectric layer made of different materials is formed, as the etching rates of the wet etching process and the dry etching process for different dielectric material are different from each other (e.g. the etching rate is gradually decreased during etching the multi-layered dielectric layer from the upper level dielectric layer to the lower level dielectric layer), a funnel-shaped opening is formed in the multi-layered dielectric layer.

Nevertheless, in the aforementioned methods, it is necessary to simultaneously perform the wet etching process and the dry etching process and even the multi-layered dielectric layer should be made of different materials. Therefore, the complexity of the method for forming the funnel-shaped opening is increased.

### SUMMARY OF THE INVENTION

The present invention is directed to a method for forming a funnel-shaped opening capable of simplifying a process of manufacturing the funnel-shaped opening.

The present invention provides a method of forming a funnel-shaped opening. First, a substrate having a conductive layer formed thereon is provided. Then, a dielectric layer is formed over the conductive layer. Further, a first opening is formed in the dielectric layer, wherein the first opening exposes the conductive layer. Thereafter, a portion of the dielectric layer at a top corner of the first opening is removed to form a second opening by an etching gas containing argon in a reaction chamber, wherein a power of the reaction chamber is about 500˜1800 W.

According to one embodiment of the present invention, the power of the reaction chamber is about 800˜1200 W.

According to one embodiment of the present invention, a flow rate of the argon is about 300˜800 sccm.

According to one embodiment of the present invention, in the step of forming the second opening, a temperature of the reaction chamber is about 20˜60° C.

According to one embodiment of the present invention, the aforementioned etching gas removes the portion of the dielectric layer at the top corner of the first opening in a first etching rate, and the etching gas removes a portion of the dielectric layer at a top surface of the dielectric layer in a second etching rate, wherein the first etching rate is much larger than the second etching rate.

According to one embodiment of the present invention, the aforementioned first etching rate is larger than the second etching rate by at least 1000 times.

According to one embodiment of the present invention, the aforementioned first opening is formed with a sidewall substantially perpendicular to a top surface of the dielectric layer.

According to one embodiment of the present invention, the aforementioned second opening comprises a tapered upper sidewall and a lower sidewall substantially perpendicular to a top surface of the conductive layer, and the lower sidewall communicates with the tapered upper sidewall.

In one embodiment of the present invention, the aforementioned etching gas further includes a gas composed by at least an element selected from a group constituted by carbon, hydrogen, halogen, argon and the combination thereof.

The present invention further provides a method of forming a funnel-shaped opening. First, a substrate having a conductive layer formed thereon is provided. Then, a barrier layer and a dielectric layer are sequentially formed on the substrate. Further, a first opening is formed in the dielectric layer, wherein the first opening exposes the barrier layer. Thereafter, a portion of the dielectric layer at a top corner of the first opening is removed to form a second opening by an etching gas containing argon in a reaction chamber, wherein a power of the reaction chamber is about 500˜1800 W. Then, a portion of the barrier layer exposed by the second opening is removed to expose the conductive layer.

According to one embodiment of the present invention, a material of the conductive layer includes copper.

According to one embodiment of the present invention, the power of the reaction chamber is about 800˜1200 W.

According to one embodiment of the present invention, a flow rate of the argon is about 300˜800 sccm.

According to one embodiment of the present invention, in the step of forming the second opening, a temperature of the reaction chamber is about 20˜60° C.

According to one embodiment of the present invention, the aforementioned etching gas removes the portion of the dielectric layer at the top corner of the first opening in a first etching rate, and the etching gas removes a portion of the dielectric layer at a top surface of the dielectric layer in a second etching rate, wherein the first etching rate is much larger than the second etching rate.

According to one embodiment of the present invention, the aforementioned first etching rate is larger than the second etching rate by at least 1000 times.

According to one embodiment of the present invention, the aforementioned first opening is formed with a sidewall substantially perpendicular to a top surface of the dielectric layer.

According to one embodiment of the present invention, the aforementioned second opening includes a tapered upper sidewall and a lower sidewall substantially perpendicular to a top surface of the barrier layer, and the lower sidewall communicates with the tapered upper sidewall.

According to one embodiment of the present invention, the aforementioned etching gas further includes a gas composed by at least an element selected from a group constituted by carbon, hydrogen, halogen, argon and the combination thereof.

According to one embodiment of the present invention, the material of the material of the aforementioned dielectric layer includes silicon oxide or silicon nitride.

According to one embodiment of the present invention, the material of the aforementioned barrier layer includes silicon carbide, silicon oxycarbide or silicon carbon nitride.

According to one embodiment of the present invention, a chemical agent for removing the portion of the barrier layer includes hydrogen (H) and fluorine (F).

According to the aforementioned description, in the present invention, the portion of the dielectric layer at the top corner of the first opening is removed by the etching gas containing argon to form the second opening with the funnel shape. Comparing with the conventional method for forming the funnel-shaped opening by simultaneously performing the dry etching process and the wet etching process, the method for forming the funnel-shaped opening provided by the present invention is relatively simple. Moreover, since the etching gas barely etches the top surface of the dielectric layer, the funnel-shaped opening possesses a predetermined depth.

To make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views showing a method for forming a funnel-shaped opening according to the first embodiment of the present invention.

FIGS. 2A through 2E are cross-sectional schematic views showing a method for forming a funnel-shaped opening according to the second embodiment of the present invention.

### DESCRIPTION OF EMBODIMENTS

### First Embodiment

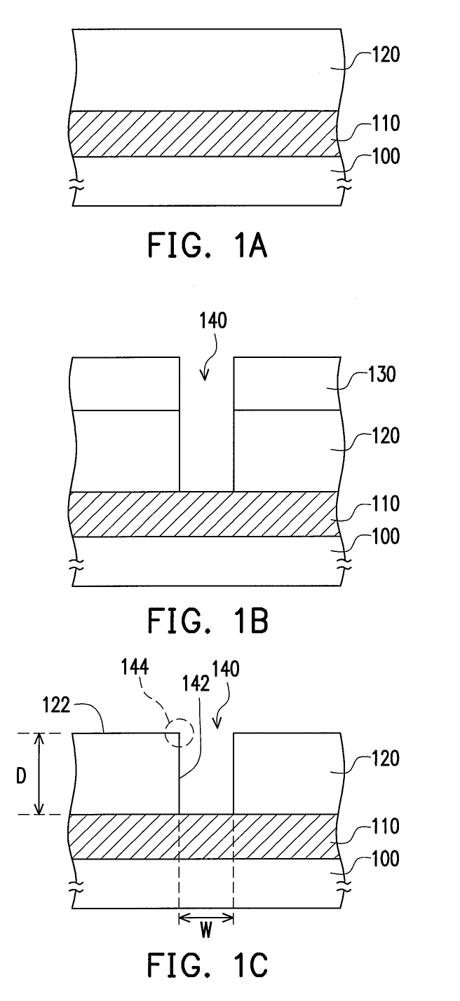

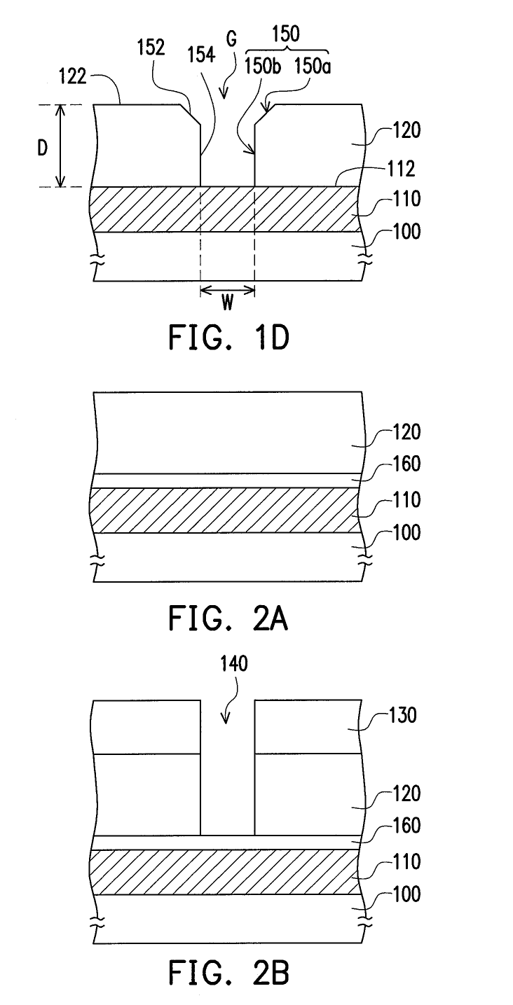

FIGS. 1A through 1D are schematic cross-sectional views showing a method for forming a funnel-shaped opening according to the first embodiment of the present invention.

As shown in FIG. 1A, a substrate 100 is provided at first, and the substrate 100 has a conductive layer 110 formed thereon. Then, a dielectric layer 120 is formed over the conductive layer 110. The substrate 100 is, for example, a silicon substrate. The conductive layer 110 can be, for example, a conductive wire formed in an interconnection. The material of the dielectric layer 120 is, for example, silicon oxide, silicon nitride or other suitable dielectric materials and the method for forming the dielectric layer 120 is, for example, the chemical vapor deposition.

As shown in FIG. 1B, thereafter, a patterned photoresist layer 130 is formed on the dielectric layer 120. A portion of the dielectric layer 120 is removed to form a first opening 140 in the dielectric layer 120 by using the patterned photoresist layer 130 as a mask, wherein the first opening 140 exposes the conductive layer 110. Furthermore, the method for removing the portion of the dielectric layer 120 can be, for example, a dry etching process with the use of a mixture gas containing fluorine.

Thereafter, as shown in FIG. 1C, the patterned photoresist layer 130 is removed. In the present embodiment, the sidewall 142 of the first opening 140 is substantially perpendicular to the top surface 122 of the dielectric layer 120. Therefore, the angle of the top corner 144 of the first opening 140 is about a right angle, and the first opening 140 is formed with a width W and a depth D. Moreover, the first opening 140 can be, for example, an opening with a relatively large aperture ratio.

As shown in FIG. 1C and FIG. 1D, a portion of the dielectric layer 120 at the top corner 144 of the first opening 140 is removed to form a second opening 150 by an etching gas G containing argon in a reaction chamber. The power of the reaction chamber is about 500˜1800 W. In the present embodiment, taking the etching gas G composed of argon as an example, the flow rate of the argon is about 300˜800 sccm, the power of the reaction chamber is about 800˜1200 W and the temperature of the reaction chamber is about 20˜60° C. It should be noticed that, under the aforementioned process conditions, the etching gas G containing argon removes the portion of the dielectric layer 120 at the top corner 144 of the first opening 140 in a first etching rate, and the etching gas G removes a portion of the dielectric layer 120 at the top surface 122 of the dielectric layer 120 in a second etching rate, and the first etching rate is much larger than the second etching rate, i.e. the first etching rate is larger than the second etching rate by at least 1000 times. In the present embodiment, the ratio of the first etching rate to the second etching rate is about infinite. In other words, from a macro point of view, the etching gas G only etches the portion of the dielectric layer 120 at the top corner 144 and barely etches the top surface 122 of the dielectric layer 120, the sidewall 142 of the first opening 140 and the conductive layer 110 exposed by the first opening 140.

Therefore, after the etching gas G removes the portion of the dielectric layer 120 at the top corner 144 of the first opening 140, the second opening 150 is formed with a tapered upper sidewall 152 and a lower sidewall 154 substantially perpendicular to the top surface 112 of the conductive layer 110. Further, the lower sidewall 154 communicates with the tapered upper sidewall 152. More clearly, the second opening 150 is formed in a funnel shape comprising an opening portion 150b composed of the lower sidewall 154 and a cone-shaped or bowl-shaped opening portion 150a composed of the tapered upper sidewall 152. In the present embodiment, the second opening 150 can be, for example, formed with the depth D and the opening portion 150b can be, for example, formed with the width W. In other words, the width W of the bottom of the second opening 150 and the depth D of the second opening 150 are substantially equal to the width W and the depth D of the first opening 140. Moreover, although the etching gas composed of argon is used as an example in the present invention, argon can be used as the major composition of the etching gas G and the etching gas G further includes a gas composed by at least an element selected from a group constituted by carbon, hydrogen, halogen, argon and the combination thereof. The gas can be, for example, Ar, CF₄, CHF₃ or H₂. In addition, by changing the parameters such as the power of the reaction chamber or the etching time, the inclination of the tapered upper sidewall 152 of the second opening 150 can be controlled. That is, the opening profile of the funnel-shaped opening can be properly formed by demand.

In the present embodiment, the portion of the dielectric layer 120 at the top corner 144 of the first opening 140 is removed by the etching gas G containing argon to form the second opening 150 with the funnel shape. Comparing with the conventional method for forming the funnel-shaped opening by simultaneously performing the dry etching process and the wet etching process, the method for forming the funnel-shaped opening provided by the present invention is relatively simple and can be combined with the conventional process. In addition, in the present embodiment, the difference between the etching rate of the etching gas G etching the portion of the dielectric layer 120 at the top corner 144 of the first opening 140 and the etching rate of the etching gas G etching the top surface 122 of the dielectric layer 120 is large so that the top surface 122 of the dielectric layer 120 is barely etched and the second opening 150 with the funnel shape is formed with a predetermined depth D. In the other words, the funnel-shaped opening formed by performing the aforementioned method possesses a better opening profile and the aforementioned method is relatively simpler. Therefore, the later formed metal material possesses relatively better step coverage so that the device properties of the semiconductor device can be improved.

### Second Embodiment

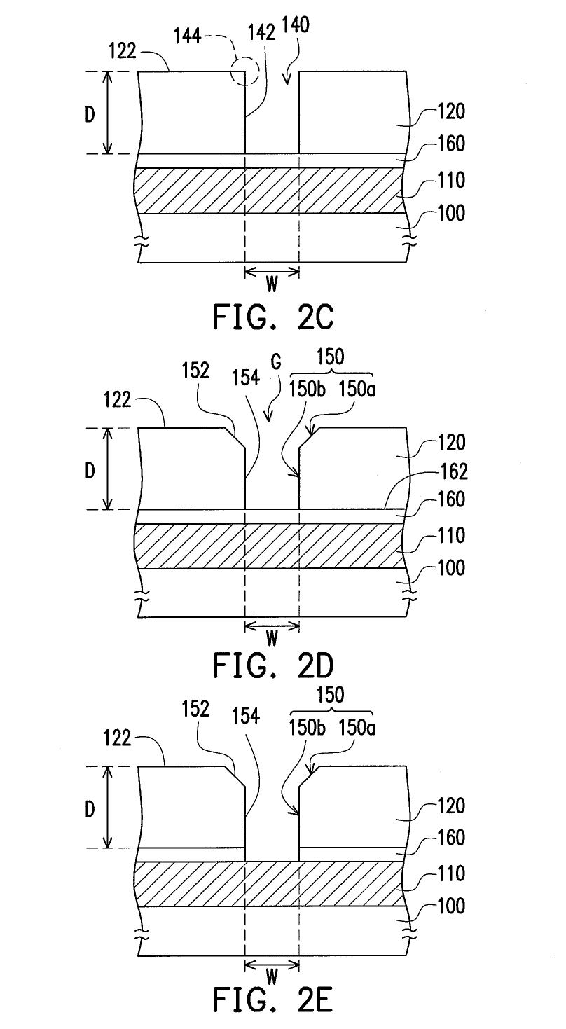

FIGS. 2A through 2E are cross-sectional schematic views showing a method for forming a funnel-shaped opening according to the second embodiment of the present invention.

As shown in FIG. 2A, a substrate 100 is provided at first, and the substrate 100 has a conductive layer 110 formed thereon. Then, a barrier layer 160 and a dielectric layer 120 are sequentially formed over the conductive layer 110. In the present embodiment, the substrate 100 is, for example, a silicon substrate. A material of the conductive layer 110 is, for example, copper and the conductive layer 110 can be, for example, a copper line. The material of the barrier layer 160 can be, for example, silicon carbide, silicon oxycarbide or silicon carbon nitride. The method for forming the barrier layer 160 can be, for example, a chemical vapor deposition process. The material of the dielectric layer 120 can be, for example, silicon oxide, silicon nitride or other suitable dielectric materials and the method for forming the dielectric layer 120 can be, for example, the chemical vapor deposition.

As shown in FIG. 2B, thereafter, a patterned photoresist layer 130 is formed on the dielectric layer 120. A portion of the dielectric layer 120 is removed to form a first opening 140 in the dielectric layer 120 by using the patterned photoresist layer 130 as a mask, wherein the first opening 140 exposes the barrier layer 160. Furthermore, the method for removing the portion of the dielectric layer 120 can be, for example, a dry etching process with the use of a mixture gas containing fluorine.

Thereafter, as shown in FIG. 2C, the patterned photoresist layer 130 is removed. In the present embodiment, the sidewall 142 of the first opening 140 is substantially perpendicular to the top surface 122 of the dielectric layer 120. Therefore, the angle of the top corner 144 of the first opening 140 is about a right angle, and the first opening 140 is formed with a width W and a depth D. Moreover, the first opening 140 can be, for example, an opening with a relatively large aperture ratio.

As shown in FIG. 2D, a portion of the dielectric layer 120 at the top corner 144 of the first opening 140 is removed to form a second opening 150 by an etching gas G containing argon in a reaction chamber. The power of the reaction chamber is about 500˜1800 W. In the present embodiment, taking the etching gas G composed of argon as an example, the flow rate of the argon is about 300˜800 sccm, the power of the reaction chamber is about 800˜1200 W and the temperature of the reaction chamber is about 20˜60° C. It should be noticed that, under the aforementioned process conditions, the etching gas G containing argon removes the portion of the dielectric layer 120 at the top corner 144 of the first opening 140 in a first etching rate, and the etching gas G removes a portion of the dielectric layer 120 at the top surface 122 of the dielectric layer 120 in a second etching rate, and the first etching rate is much larger than the second etching rate, i.e. the first etching rate is larger than the second etching rate by at least 1000 times. In the present embodiment, the ratio of the first etching rate to the second etching rate is about infinite. Moreover, since the etching selectivity ratio of the material of the dielectric layer 120 to the material of the barrier layer 160 is large, the etching gas G does not etch the barrier layer 160 exposed by the first opening 140. In other words, from a macro point of view, the etching gas G only etches the portion of the dielectric layer 120 at the top corner 144 and barely etches the top surface 122 of the dielectric layer 120, the sidewall 142 of the first opening 140 and the barrier layer 160 exposed by the first opening 140.

Therefore, after the etching gas G removes the portion of the dielectric layer 120 at the top corner 144 of the first opening 140, the second opening 150 is formed with a tapered upper sidewall 152 and a lower sidewall 154 substantially perpendicular to the top surface 162 of the barrier layer 160. Further, the lower sidewall 154 communicates with the tapered upper sidewall 152. More clearly, the second opening 150 is formed in a funnel shape comprising a opening portion 150b composed of the lower sidewall 154 and a cone-shaped or bowl-shaped opening portion 150a composed of the tapered upper sidewall 152. In the present embodiment, the second opening 150 can be, for example, formed with the depth D and the opening portion 150b can be, for example, formed with the width W. In other words, the width W of the bottom of the second opening 150 and the depth D of the second opening 150 is substantially equal to the width W and the depth D of the first opening 140. Moreover, although the etching gas composed of argon is used as an example in the present invention, argon can be used as the major composition of the etching gas G and the etching gas G further includes a gas composed by at least an element selected from a group constituted by carbon, hydrogen, halogen, argon and the combination thereof. The gas can be, for example, Ar, CF₄, CHF₃ or H₂. In addition, by changing the parameters such as the power of the reaction chamber or the etching time, the inclination of the tapered upper sidewall 152 of the second opening 150 can be controlled. That is, the opening profile of the funnel-shaped opening can be properly formed by demand.

It should be noticed that, when the conductive layer is made of copper, the existence of the barrier layer 160 becomes more important. Because the copper easily sputters under the ion bombardment, it is possible for the copper in the conductive layer 110 to sputter onto the sidewall 142 of the first opening 140 under the ion bombardment if the copper conductive layer 110 is exposed by the first opening 140. Thus, the later performed processes and the properties of the semiconductor device are seriously affected. However, in the present embodiment, the barrier layer 160 is formed to protect the conductive layer 110 to avoid the problems mentioned above.

Then, as shown in FIG. 2E, a portion of the barrier layer 160 exposed by the second opening 150 is removed to expose the conductive layer 110. In the present embodiment, the method for removing the portion of the barrier layer includes using a chemical agent including_hydrogen (H) and fluorine (F), for example. Therefore, the conductive layer 110 can be protected from sputtering or being damaged by the ion bombardment while the barrier layer 160 is removed.

In the present embodiment, the portion of the dielectric layer 120 at the top corner 144 of the first opening 140 is removed by the etching gas G containing argon to form the second opening 150 with the funnel shape. Comparing with the conventional method for forming the funnel-shaped opening by simultaneously performing the dry etching process and the wet etching process, the method for forming the funnel-shaped opening provided by the present invention is relatively simple and can be combined with the conventional process. In addition, in the present embodiment, the difference between the etching rate of the etching gas G etching the portion of the dielectric layer 120 at the top corner 144 of the first opening 140 and the etching rate of the etching gas G etching the top surface 122 of the dielectric layer 120 is large so that the top surface 122 of the dielectric layer 120 is barely etched and the second opening 150 with the funnel shape is formed with a predetermined depth D. Furthermore, since the barrier layer 160 can protect the conductive layer 110 from being affected by the etching gas G, the method for forming the funnel-shaped opening provided by the present embodiment is especially suitable for manufacturing the via or the contact window for connecting the copper wires. In the other words, the funnel-shaped opening formed by performing the aforementioned method possesses a better opening profile and the aforementioned method is relatively simpler. Therefore, the later formed metal material possesses relatively better step coverage so that the device properties of the semiconductor device can be improved.

According to the aforementioned description, in the present invention, the portion of the dielectric layer at the top corner of the first opening is removed by the etching gas containing argon to form the second opening with the funnel shape.

Comparing with the conventional method for forming the funnel-shaped opening by simultaneously performing the dry etching process and the wet etching process, the method for forming the funnel-shaped opening provided by the present invention is relatively simple and can be combined with the conventional process. Moreover, since the etching gas barely etches the top surface of the dielectric layer, the funnel-shaped opening possesses a predetermined depth. In the other words, the funnel-shaped opening formed by performing the aforementioned method possesses a better opening profile and the aforementioned method is relatively simpler. Therefore, the later formed metal material possesses relatively better step coverage so that the device properties of the semiconductor device can be improved.

Although the invention has been described with reference to the above embodiments, it is apparent to one of the ordinary skill in the art that modifications to the described embodiments may be made without departing from the spirit of the invention. Accordingly, the scope of the invention will be defined by the attached claims not by the above detailed descriptions.

What is claimed is:

1. A method of forming a funnel-shaped opening, the method comprising:
providing a substrate having a conductive layer formed thereon;
forming a dielectric layer over the conductive layer;
forming a first opening in the dielectric layer, wherein the first opening exposes the conductive layer; and
removing a portion of the dielectric layer at a top corner of the first opening by an etching gas containing argon in a reaction chamber, so as to form a second opening, wherein a power of the reaction chamber is about 500˜1800 W.

2. The method of claim 1, wherein the power of the reaction chamber is about 800˜1200 W.

3. The method of claim 1, wherein a flow rate of the argon is about 300˜800 sccm.

4. The method of claim 1, wherein in the step of forming the second opening, a temperature of the reaction chamber is about 20˜60° C.

5. The method of claim 1, wherein the etching gas removes the portion of the dielectric layer at the top corner of the first opening in a first etching rate, and the etching gas removes a portion of the dielectric layer at a top surface of the dielectric layer in a second etching rate, wherein the first etching rate is much larger than the second etching rate.

6. The method of claim 5, wherein the first etching rate is larger than the second etching rate by at least 1000 times.

7. The method of claim 1, wherein a sidewall of the first opening is substantially perpendicular to a top surface of the dielectric layer.

8. The method of claim 1, wherein the second opening comprises a tapered upper sidewall and a lower sidewall substantially perpendicular to a top surface of the conductive layer, and the lower sidewall communicates with the tapered upper sidewall.

9. The method of claim 1, wherein the etching gas comprises a gas composed by at least an element selected from a group constituted by carbon, hydrogen, halogen, argon and the combination thereof.

10. A method of forming a funnel-shaped opening, the method comprising:
providing a substrate having a conductive layer formed thereon;
forming a barrier layer and a dielectric layer on the substrate in sequence;
forming a first opening in the dielectric layer, wherein the first opening exposes the barrier layer;
removing a portion of the dielectric layer at a top corner of the first opening by an etching gas containing argon in a reaction chamber, so as to form a second opening, wherein a power of the reaction chamber is about 500˜1800 W; and
removing a portion of the barrier layer exposed by the second opening to expose the conductive layer.

11. The method of claim 10, wherein the material of the conductive layer comprises copper.

12. The method of claim 10, wherein the power of the reaction chamber is about 800˜1200 W.

13. The method of claim 10, wherein a flow rate of the argon is about 300˜800 sccm.

14. The method of claim 10, wherein in the step of forming the second opening, a temperature of the reaction chamber is about 20˜60° C.

15. The method of claim 10, wherein the etching gas removes the portion of the dielectric layer at the top corner of the first opening in a first etching rate, and the etching gas removes a portion of the dielectric layer at a top surface of the dielectric layer in a second etching rate, wherein the first etching rate is much larger than the second etching rate.

16. The method of claim 15, wherein the first etching rate is larger than the second etching rate by at least 1000 times.

17. The method of claim 10, wherein a sidewall of the first opening is substantially perpendicular to a top surface of the dielectric layer.

18. The method of claim 10, wherein the second opening comprises a tapered upper sidewall and a lower sidewall substantially perpendicular to a top surface of the barrier layer, and the lower sidewall communicates with the tapered upper sidewall.

19. The method of claim 10, wherein the etching gas includes a gas composed by at least an element selected from a group constituted by carbon, hydrogen, halogen, argon and the combination thereof.

20. The method of claim 10, wherein the material of the dielectric layer includes silicon oxide or silicon nitride.

21. The method of claim 10, wherein the material of the barrier layer includes silicon carbide, silicon oxycarbide or silicon carbon nitride.

22. The method of claim 10, wherein a chemical agent for removing the portion of the barrier layer includes hydrogen (H) and fluorine (F).
